(19) United States
(12) Patent Application Publication
(10) Pub. No.: US 2026/0122947 A1
(43) Pub. Date: Apr. 30, 2026

(54) HIGH ELECTRON MOBILITY TRANSISTOR AND METHOD OF MANUFACTURING THEREOF

(71) Applicant: Soitec Belgium, Hasselt (BE)

(72) Inventors: Joff Derluyn, Hasselt (BE); Prem Kumar Kandaswamy, Hasselt (BE)

(21) Appl. No.: 18/853,986

(22) PCT Filed: Mar. 30, 2023
(86) PCT No.: PCT/EP2023/058374

§ 371 Date: Oct. 3, 2024

(30) Foreign Application Priority Data
Apr. 5, 2022 (FR) FR2203125

(51) Int. Cl. H10D 30/47; H10D 30/01; H10D 62/85

(52) U.S. Cl. CPC H10D 30/475; H10D 30/015; H10D 62/8503

(57) ABSTRACT

A method of manufacturing a high electron mobility transistor comprises:—providing a target wafer comprising a target substrate;—providing a donor wafer comprising an epitaxial donor film;—bonding the donor film to the target wafer;—separating the donor wafer and the target wafer along the first donor III-N layer, thereby forming on the target wafer a top surface layer of 200 nm or less;—epitaxially growing an epitaxial III-N semiconductor layer stack on top of the top surface layer;—forming a gate contact in a gate region; and forming a substrate galvanic contact contacting the target substrate.

### CROSS-REFERENCE TO RELATED APPLICATIONS

This application is a national phase entry under 35 U.S.C. § 371 of International Patent Application PCT/EP2023/058374, filed Mar. 30, 2023, designating the United States of America and published as International Patent Publication WO 2023/194211 A1 on Oct. 12, 2023, which claims the benefit under Article 8 of the Patent Cooperation Treaty of French Patent Application Serial No. FR2203125, filed Apr. 5, 2022.

### TECHNICAL FIELD

The present disclosure generally relates, amongst others, to a semiconductor structure and to a method of growing thereof. More particularly, it relates to a high electron mobility transistor comprising nitride-based active layers, wherein the high electron mobility transistor achieves outstanding performance for high-power and high-frequency applications, and to a method of manufacturing thereof.

### BACKGROUND

Semiconductor devices comprising, for example, gallium nitride, also referred to as GaN, and/or Group III-nitride-based heterostructures such as, for example, InAlGaN/GaN heterostructures, can carry large currents and support high voltages. This makes them increasingly desirable for power semiconductor devices. In general, the manufactured devices for high power/high frequency applications are based on device structures that exhibit high electron mobility and high critical electric field, and are referred to as, for example, heterojunction field effect transistors, also called HFETs, high electron mobility transistors, also called HEMTs, or modulation doped field effect transistors, also called MODFETs. HEMTs are, for example, useful for analog circuit applications, such as RF/microwave power amplifiers or power switches. Such devices can typically withstand high voltages, e.g., up to 1,000 Volts, or operate at high frequencies, e.g., from 100 kHz to 100 GHz.

HEMTs comprising GaN are typically manufactured on top of conventional substrates, such as, for example, semi-insulating silicon carbide substrates, also referred to as SiC, or high-resistive silicon substrates. For high-power and high-frequency applications, it is indeed essential to maximize the resistivity of the underlying substrate of the devices. The growth of GaN HEMTs typically starts with the growth of an AlN nucleation layer on top of the substrate. Such AlN nucleation layer usually demonstrates a high threading dislocation density. To obtain a better crystal quality when growing the GaN HEMT on top of the AlN nucleation layer, i.e., to obtain a lower threading dislocation density when growing the GaN HEMT on top of the AlN nucleation layer, it is custom to grow, for example, a 1 μm-thick GaN buffer layer on top of the AlN nucleation layer.

Such GaN HEMTs are prone to trapping effects, both from the surface of the HEMT and from the GaN buffer layer or the GaN bulk layer grown on top of the AlN nucleation layer. The traps in the GaN buffer/bulk layer are the result from intentional impurities, such as, for example, carbon or iron, that are introduced in the GaN buffer/bulk layer to make the GaN buffer/bulk layer more resistive. Adding these intentional impurities allows to obtain higher breakdown voltage and lower leakage for the GaN HEMTs. In other words, the GaN buffer/bulk layer always has background impurities to increase the confinement, thereby introducing trapping effects for the resulting GaN HEMTs.

Additionally, such a GaN buffer layer creates a thermal impedance between the active GaN HEMT and the heat sink at the bottom of the substrate onto which the active GaN HEMT is manufactured, causing degraded performance and jeopardizing the reliability of the GaN HEMT. Similarly, when growing GaN HEMTs on top of silicon substrates, besides the AlN nucleation layer, a strain management buffer must be grown in addition to the GaN buffer layer. This increases the total thickness of the layer stack up to, for example, 2 μm. These buffer layers constitute a large thermal impedance for the GaN HEMTs.

With the ever-increasing need for high-power and high-frequency solutions, the telecommunication industry is faced with the challenge of making such Group III-nitride-based active devices compatible with existing technologies. For example, Group III-nitride-based active devices should allow the continued miniaturization of microelectronic devices and the continued improvement of their performance.

### BRIEF SUMMARY

It is thus an object of embodiments of the present disclosure to propose a high electron mobility transistor and a manufacturing method thereof that do not show the inherent shortcomings of the prior art. More specifically, it is an object of embodiments of the present disclosure to propose a high electron mobility transistor with improved performance and reliability at high-power and high-frequency and a manufacturing method thereof.

There is a need for a high electron mobility transistor that demonstrates improved resistivity, and reduced power losses and linearity problems. Additionally, there is a need for a semiconductor structure that, from a manufacturing perspective, is compatible with existing technologies.

There is a need for a high electron mobility transistor that can be grown on any substrate, and that demonstrates reduced thermal impedance. There is also a need for a high electron mobility transistor of which certain properties and parameters can be controlled or changed through the substrate onto which the high electron mobility transistor is grown. Finally, there is a need for a high electron mobility transistor for which trapping effects are minimized or even eliminated.

This object is achieved, according to a first example aspect of the present disclosure, by a method of manufacturing a high electron mobility transistor, the method comprising the steps of:
providing a target wafer comprising a target substrate;
providing a donor wafer, wherein the providing the donor wafer comprises:
   providing a sacrificial substrate;
   forming a donor film on top of the sacrificial substrate; wherein the donor film comprises a first donor III-N layer;
bonding the donor film to the target wafer;
separating the donor wafer and the target wafer by splitting the first donor III-N layer, or separating the donor wafer and the target wafer at the interface between the first donor III-N layer and the sacrificial substrate, thereby forming on the target wafer a top surface layer at least partially comprising the first donor III-N layer bonded onto the target wafer, wherein a thickness of the top surface layer is equal to or lower than 200 nm;
epitaxially growing an epitaxial III-N semiconductor layer stack on top of the top surface layer, wherein the epitaxial III-N semiconductor layer stack comprises:
   a first active III-N layer;
   a second active III-N layer on top of the first active III-N layer;
   with a two-dimensional Electron gas between the first active III-N layer and the second active III-N layer;
forming a gate contact contacting the second active III-N layer in a gate region; and
forming a substrate galvanic contact contacting the target substrate.

The method according to the present disclosure allows to grow a high electron mobility transistor on any substrate, even, for example, foreign substrates. The method, according to the present disclosure, allows to manufacture a high electron mobility transistor from an epitaxial III-N semiconductor layer stack grown on top of a top surface layer bonded onto, i.e., transferred onto by SMART CUT™, for example, a silicon substrate, such as, for example, a high-resistive silicon substrate, or a SiC substrate, such as, for example, a semi-insulating SiC substrate, or a Silicon-On-Insulator substrate, or a germanium substrate, or a germanium-on-insulator substrate, or a sapphire substrate, etc. Additionally, the method according to the present disclosure allows bonding the donor film to the target wafer without having to provide a buffer layer on the target wafer between the substrate and the high electron mobility transistor prior to bonding. In other words, a buffer layer must not be grown onto the target substrate prior to bonding the donor film onto the target substrate. The high electron mobility transistors manufactured with the method according to the present disclosure are therefore less prone to trapping effects than prior art high electron mobility transistors grown, for example, on semi-insulating SiC substrates or on high-resistive Si substrates.

Another advantage of the method according to the present disclosure is the improved thermal impedance of the manufactured high electron mobility transistors. Thanks to the lack of buffer layers between the epitaxial III-N semiconductor layer stack and the target substrate, and thanks to the thickness of the transferred first donor III-N layer that is kept as thin as possible, and thanks to the limited thickness of the total layer stack formed on the target wafer, low thermal resistivity can be achieved for the high electron mobility transistor. In other words, there is less thermal impedance between the heat sink at the bottom of the substrate and the active device such as, for example, the high electron mobility transistor manufactured with the method according to the present disclosure. The thickness of the first donor III-N layer transferred onto the target substrate is kept as low as possible, and this layer is maximum 200 nm thick, preferably less than 100 nm thick, preferably less than 50 nm thick.

An additional advantage of the method according to the present disclosure, is that the thin layer stack formed on top of the target wafer enables the use of the substrate as a fourth terminal for the high electron mobility transistor. This way, the substrate galvanic contact contacting the target substrate can indeed be used to impose a bottom side voltage bias on the target substrate relative to the source contact of the high electron mobility transistor. Thanks to the low thickness of the layers between the bottom side of the target substrate and the 2 DEG, this substrate galvanic contact can in turn be used to control or change certain properties or parameters of the high electron mobility transistor, such as, for example, the threshold voltage and/or the off-state leakage of the high electron mobility transistor. The substrate galvanic contact can also be used to modulate, for example, the charging state of the buffer or bulk traps present in the target substrate, thereby minimizing or eliminating trapping effects of the high electron mobility transistor, and thereby reducing memory effects in the high electron mobility transistor. The substrate galvanic contact may be formed on the bottom side of the target substrate and substantially below a gate region of the high electron mobility transistor manufactured on the target wafer after bonding and epitaxial growth of the epitaxial III-N semiconductor layer stack. Alternatively, the substrate galvanic contact may be formed on the bottom side of the target substrate and substantially below the high electron mobility transistor manufactured on the target wafer after bonding and epitaxial growth of the epitaxial III-N semiconductor layer stack.

With existing prior art solutions, when a high electron mobility transistor is manufactured, for example, on a SiC substrate, as SiC substrates in RF applications are typically very highly resistive, for example, demonstrating a resistivity higher than 1·10⁵ Ohm·cm, it is very challenging to have any impact on the properties of the active GaN HEMT device through the substrate. When a high electron mobility transistor is manufactured, for example, on a high-resistive substrate in existing prior art solutions, a very high bias voltage, for example, larger than 100V, is required to have any impact on the active HEMT device, because of the thick buffer stack between the active HEMT device and the substrate. Contrary to these prior art solutions, the method according to the present disclosure does not require a very high voltage to be applied via the substrate galvanic contact to have an effect on the properties of the active devices manufactured on top of the target substrate as the total thickness of the layer stack between the substrate and the 2 DEG is kept low.

In the context of the present disclosure, forming the donor film on top of the sacrificial substrate comprises providing a first donor III-N layer, wherein the first donor III-N layer is epitaxially grown. For example, forming the donor film on top of the sacrificial substrate comprises epitaxially growing the first donor III-N layer on top of the sacrificial substrate. In the context of the present disclosure, the first donor III-N layer comprises GaN. The first donor III-N layer, for example, comprises N-polar GaN epitaxially grown on the donor wafer by MOCVD or by MBE. The donor wafer is turned upside-down, and the first donor III-N layer is bonded on the top side of the target wafer. The donor wafer and the target wafer are then bonded together. This way, the first donor III-N layer bonded on the top side of the target wafer is Ga-polar. The density of threading dislocations in the epitaxial III-N semiconductor layer stack grown on top of the top surface layer is thereby minimized. Alternatively, the first donor III-N layer, for example, comprises GaN provided on the donor wafer after having been grown on a temporary wafer by MOCVD or by MBE as a Ga-polar layer and being bonded upside side to the donor wafer using SMART CUT™ technology. The donor wafer and the target wafer are separated from each other by SMART CUT™ of the first donor III-N layer of the donor film. In the context of the present disclosure, an interface is formed between the first donor III-N layer and the sacrificial substrate, wherein the first donor III-N layer and the sacrificial substrate come in contact. The separation of the donor wafer from the target wafer by SMART CUT™ at the level of the first donor III-N layer happens by causing the first donor III-N layer to break at the interface between the first donor III-N layer and the sacrificial substrate. In other words, the first donor III-N layer is cut at the interface between the first donor III-N layer and the sacrificial substrate. This separation forms on the target wafer a top surface layer comprising the first donor III-N layer initially grown on the sacrificial substrate and bonded onto the target wafer, wherein a thickness of the top surface layer on the target wafer substantially corresponds to the thickness of the first donor III-N layer grown onto the sacrificial substrate. According to the present disclosure, a thickness of the top surface layer is equal to or lower than 200 nm on the target wafer. Alternatively, the separation of the donor wafer from the target wafer by SMART CUT™ at the level of the first donor III-N layer happens by causing the first donor III-N layer to split, thereby leaving a first remaining portion of first donor III-N layer on the sacrificial substrate separated from the target substrate, which will be later on referred to as the top surface layer, and also leaving a second remaining portion of first donor III-N layer on the target substrate, which will be later on referred to as the donor surface layer, wherein a sum of a thickness of the first remaining portion and of a thickness of the second remaining portion substantially corresponds to the total thickness of the first donor III-N layer grown on the sacrificial substrate prior to bonding. In other words, the first donor III-N layer is split within its thickness. This separation forms on the target wafer a top surface layer comprising at least partially the first donor III-N layer initially grown on the sacrificial substrate and bonded onto the target wafer, wherein a thickness of the top surface layer on the target wafer is equal to or lower than 200 nm.

In the context of the present disclosure, a donor wafer is, for example, a wafer with a diameter of 125 mm or 150 mm or 200 mm or 300 mm. Alternatively, in the context of the present disclosure, a donor wafer, for example, comprises a plurality of dies or tiles of a few mm² or of a few cm² of the material of the first donor III-N layer. In the context of the present disclosure, a target wafer is, for example, a wafer with a diameter of 125 mm or 150 mm or 200 mm or 300 mm, wherein a diameter of the target wafer is larger than a diameter of the donor wafer. This way, for example, one donor wafer can be bonded onto one target wafer. Alternatively, for example, several donor wafers can be bonded onto one target wafer, thereby increasing the manufacturing yield.

In the context of the present disclosure, a sacrificial substrate is one of the following: a silicon substrate, a silicon-on-insulator substrate, a silicon carbide substrate, a sapphire substrate, a germanium substrate, a germanium-on-insulator substrate, or any other suitable alternative to the above. Other alternatives for the sacrificial substrate are described below.

In the context of the present disclosure, a target substrate is one of the following: a silicon substrate, a silicon-on-insulator substrate, a silicon carbide substrate, a sapphire substrate, a germanium substrate, a germanium-on-insulator substrate, or any other suitable alternative to the above. This way, the method of manufacturing a high electron mobility according to the present disclosure is compatible with existing manufacturing techniques developed for the complementary metal-oxide-semiconductor technology and processes. In other words, the manufacturing of the high electron mobility transistor is CMOS-compatible as present features and present process steps can be integrated therein without much additional effort. This reduces the complexity and the costs associated with manufacturing such as transistor. For example, the target substrate is a silicon substrate, such as, for example, a <111> Si substrate, and combinations of thereof, and substrates comprising initial layers, such as a stack of layers. For example, a <111> Si substrate can be used when epitaxial layers must be grown on top of the Si substrate. Alternatively, the target substate is, for example, a silicon substrate, such as, for example, a <100> Si substrate. This may, for example, enable GaN/CMOS integration. Alternatively, the target substrate of the high electron mobility transistor comprises a free-standing GaN substrate, a free-standing AlN substrate.

In the context of the present disclosure, when the target substrate is a silicon-on-insulator substrate, the target substrate comprises a base layer comprising bulk silicon. A resistivity of the base layer of the silicon-on-insulator substrate is typically comprised between 3 and 5 kOhm·cm and is preferably higher than 1 kOhm·cm. This way, the resistivity of the target substrate underlying the epitaxial III-N semiconductor layer stack is maximized for high-power and high-frequency applications.

In the context of the present disclosure, the technology of silicon-on-insulator, also referred to as SOI, corresponds to the manufacturing of semiconductor devices in a layered silicon-insulator-silicon substrate. The choice of insulator depends largely on the intended application of the semiconductor devices. Several types of silicon-on-insulator substrates may be used within the context of the present disclosure.

Due to the isolation from the bulk silicon of the base layer of the silicon-on-insulator substrate, parasitic capacitance within the semiconductor devices manufactured from the Group III-nitride heterostructure is lowered, thereby improving their power consumption and their performance. The semiconductor devices manufactured on silicon-on-insulator also demonstrate a higher resistance to latch up and a higher performance at equivalent VDD than semiconductor devices integrated on other types of substrates. The temperature dependency of the semiconductor devices manufactured on SOI is reduced compared to semiconductor devices integrated on other types of substrates. Due to the isolation, the semiconductor devices manufactured on SOI demonstrate lower leakage currents and consequently higher power efficiency.

Radio-Frequency silicon-on-insulator substrates, also referred to as RF-SOI substrates, enable high RF performance on silicon films compatible with standard CMOS processes, high linearity RF isolation and power signals, low RF loss, digital processing and power management integration.

For example, an enhanced signal integrity substrate for RF application comprises a base layer comprising high-resistive silicon, a trap rich layer formed on top of the base layer, a buried insulator formed on top of the trap rich layer, and a top layer formed on top of the buried insulator, wherein the top layer comprises a monocrystal. A resistivity of the base layer is typically over 3 kOhm·cm. A thickness of the top layer is typically comprised between 50 nm and 200 nm. The addition of a trap-rich layer provides outstanding RF performances. Such substrate is particularly suited for devices with stringent linearity specifications. Applications typically target, for example, LTE-Advanced and 5G specifications and address different performance requirements. Compared to a high-resistive SOI substrate, an enhanced signal integrity substrate demonstrates better linearity, lower RF losses, lower crosstalk, improved quality factors for passives, smaller die sizes and higher thermal conductivity. Enhanced signal integrity substrates further typically demonstrate a harmonic quality factor lower than −80 dBm.

Another example of a RF-SOI comprises a base layer comprising mid-resistive silicon, a trap-rich layer formed on top of the base layer, a buried insulator formed on top of the trap-rich layer, and a top layer comprising a thin monocrystal. Such substrate is particularly suited for, for example, cost sensitive highly integrated devices, and is particularly well suited to, for example, Wi-Fi, IoT and other consumer applications specifications.

Another example of a RF-SOI called high-resistive SOI targets, for example, devices with lower linearity specifications. Such substrate comprises a base layer comprising high-resistive silicon, a buried insulator formed on top of the base layer and a top layer comprising a thin monocrystal.

Power silicon-on-insulator substrates address the requirements for integrating, for example, high-voltage and analog functions in intelligent, energy-efficient and highly reliable power IC devices, for automotive and industry markets. They provide excellent electrical isolation and are perfect for integrating devices operating at different voltages from a few volts to several hundred volts while reducing die area and improving reliability. These substrates are ideal for applications such as CAN/LIN transceivers, switch mode power supplies, brushless motor drivers, LED drivers, and more. A power SOI comprises a base layer comprising silicon, a buried insulator formed on top comprising oxide, and a top layer comprising silicon. A thickness of the buried insulator is typically comprised between 0.4 μm to 1 μm and a thickness of the top layer is comprised typically between 0.1 μm and 1.5 μm.

Photonics silicon-on-insulator substrates address the requirement of optical function integration onto, for example, a CMOS chip for low-cost and high-speed optical transceivers. Such a substrates comprises a base layer comprising silicon, a buried insulator formed on top of the base layer and comprising oxide, and a top layer formed on top of the buried insulator and comprising monocrystalline silicon. A thickness of the buried insulator is typically comprised between 0.7 μm to 2 μm and a thickness of the top layer is comprised typically between 0.1 μm and 0.5 μm. The crystalline silicon layer on insulator can be used to fabricate, for example, optical waveguides and other optical devices, either passive or active, e.g., through suitable implantations. The buried insulator enables, for example, the propagation of infrared light in the silicon layer on the basis of total internal reflection. The top surface of the waveguides can be either left uncovered and exposed to air, e.g., for sensing applications, or covered with a cladding, for example, made of silica.

From a manufacturing perspective, SOI substrates are compatible with most conventional fabrication processes. In general, an SOI-based process may be implemented without special equipment or significant retooling of an existing factory. Among challenges unique to SOI are novel metrology requirements to account for the buried insulator and concerns about differential stress in the top layer comprising silicon.

A two-dimensional Electron gas, also referred to as 2 DEG, is a gas of electrons free to move in two dimensions, but tightly confined in the first. This tight confinement leads to quantized energy levels for motion in that direction. The electrons appear to be a 2D sheet embedded in a 3D world. Group III-nitride-based heterostructures comprising a first active III-N layer and a second active III-N layer, such as, for example, AlGaN/GaN heterostructures, are very suited for high-power and high-frequency applications due to their high electron velocity and high critical electric field. In this heterostructure, a two-dimensional electron gas, also referred to as 2 DEG, is generated by the spontaneous and piezoelectric polarization between the first active III-N layer and the second active III-N layer, i.e., for example, between AlGaN and GaN.

In the context of the present disclosure, Group III-nitride refers to semiconductor compounds formed between elements in Group III of the periodic table, for example, Boron, also referred to as B, Aluminum, also referred to as Al, Gallium, also referred to as Ga, Indium, also referred to as In, and Nitrogen, also referred to as N. Example of binary Group III-nitride compounds are GaN, AlN, BN, etc. Group III-nitride also refers to ternary and quaternary compounds such as, for example, AlGaN and InAlGaN.

In the context of the present disclosure, the first active III-N layer comprises one or more of N, P, As, and one or more of B, Al, Ga, In and Tl. The first active III-N layer, for example, comprises GaN. The second active III-N layer comprises one or more of N, P, As, and one or more of B, Al, Ga, In, and Tl. The second active III-N layer, for example, comprises AlGaN. The term AlGaN relates to a composition comprising Al, Ga and N in any stoichiometric ratio (AlₓGa_{y}N) wherein x is comprised between 0 and 1 and y is comprised between 0 and 1. Alternatively, the second active III-N layer, for example, comprises AlN. Alternatively, the second active III-N layer comprises InAlGaN. A composition such as InAlGaN comprises In in any suitable amount. Alternatively, both first active III-N layer and second active III-N layer comprise InAlGaN, and the second active III-N layer comprises a bandgap larger than a bandgap of the first active III-N layer and wherein the second active III-N layer comprises a polarization larger than the polarization of the first active III-N layer. Alternatively, both first active III-N layer and second active III-N layer comprise BInAlGaN, and the second active III-N layer comprises a bandgap larger than a bandgap of the first active III-N layer and wherein the second active III-N layer comprises a polarization larger than the polarization of the first active III-N layer. Compositions of the active layer may be chosen in view of characteristics to be obtained, and compositions may vary accordingly.

In the context of the present disclosure, a gate contact such as, for example, a gate electrode, is provided in the gate region of the high electron mobility transistor. Forming a gate contact in the gate region comprises plurality of process steps. For example, this step comprises depositing photoresist and performing a lithography step defining the foot of the gate contact by, for example, completely removing potential passivation layers on top of the second active III-N layer such as, for example, oxide or one or more dielectric layers. Alternatively, this step comprises depositing photoresist and performing a lithography step defining the foot of the gate contact by, for example, partially removing potential passivation layers on top of the second active III-N layer such as, for example, oxide or one or more dielectric layers. In this way, some layers of the passivation layers remain below the gate of the high electron mobility transistor and form a gate dielectric to further reduce trapping effects and leakage current. The gate electrode of the gate contact is, for example, a Metal-Oxide-Semiconductor gate, also referred to MOS gate, and can be made by depositing metal stacks, such as, for example, comprising Ni, Pt, W, WN, or TiN and capped by Al, Au or Cu. Metal patterns are consecutively defined by performing lift-off of the metal on top of the photoresist. Alternatively, the gate metal stack is deposited, for example, comprising Ni, Pt, W, WN, or TiN and capped by Al, Au or Cu. Then the photoresist and the lithography steps are performed, and the thus defined photoresist patterns act as a mask for the dry etching of the metal stacks in areas where it is unwanted. Next the photoresist is removed.

According to example embodiments, providing the target wafer further comprises forming a target dielectric layer on top of the target substrate, wherein a thickness of the target dielectric layer is equal to or lower than 50 nm.

In the context of the present disclosure, the donor film of the donor wafer is bonded by direct bonding to the target substrate of the target wafer. In other words, with direct bonding, the donor film of the donor wafer directly contacts the target substrate of the target wafer.

Alternatively, in the context of the present disclosure, a target dielectric layer is provided on top of the target substrate. The target dielectric layer, for example, comprises silicon dioxide, also referred to as SiO₂. For example, the target dielectric layer is a buried oxide layer, also referred to as BOX. A thickness of the target dielectric layer is, for example, equal to or lower than 50 nm, for example, 20 nm, 10 nm, 5 nm, etc. The thickness of the target dielectric layer is therefore kept as low as possible. The target dielectric layer is used to facilitate the bonding of the donor film to the target substrate. In other words, the donor film of the donor wafer is bonded to the target dielectric layer of the target wafer.

According to example embodiments, forming the donor film further comprises forming a donor dielectric layer on top of the first donor III-N layer, wherein a thickness of donor dielectric layer is equal to or lower than 10 nm.

A donor dielectric layer is, for example, a layer of silicon nitride, such as, for example, an amorphous layer of silicon nitride. For example, the donor dielectric layer is epitaxially grown on top of the first donor III-N layer. A thickness of the donor dielectric layer is kept as thin as possible, such as, for example, 5 to 10 nm. The donor dielectric layer acts as a current blocking layer between the target substrate and the high electron mobility transistor manufactured with the method according to the present disclosure.

According to example embodiments, bonding the donor film to the target wafer corresponds to bonding the donor dielectric layer to the target dielectric layer, thereby forming a dielectric layer stack comprising the target dielectric layer and the donor dielectric layer.

A thickness of the target dielectric layer and a thickness of the donor dielectric layer are kept as low as possible, thereby ensuring a thickness of the dielectric layer stack between the target substrate and the first donor III-N layer is minimized. For example, a thickness of the dielectric layer stack is equal to or lower than 60 nm. This further improves the thermal impedance of high electron mobility transistors manufactured with the method according to the present disclosure.

Alternatively, when the donor film does not comprise a donor dielectric layer on top of the first donor III-N layer, bonding the donor film to the target wafer corresponds to bonding the first donor III-N layer directly to the target dielectric layer, thereby forming a dielectric layer stack comprising the target dielectric layer.

According to example embodiments, forming the donor film further comprises providing a second donor III-N epitaxial layer between the first donor III-N layer and the donor dielectric layer.

A second donor III-N epitaxial layer, for example, comprises aluminum nitride. For example, the second donor III-N epitaxial layer comprises epitaxially grown N-polar AlN. This second donor III-N epitaxial layer acts as a back barrier for the high electron mobility transistor manufactured after bonding the donor film to the target wafer, thereby confining the electrons into the first active III-N layer of the epitaxial III-N semiconductor layer stack. This way, there is no need to introduce impurities in the first active III-N layer, thus further reducing trapping effects.

According to example embodiments, a thickness of the second donor III-N epitaxial layer is equal to or lower than 10 nm.

This way, a thickness of the donor film on the donor wafer is kept as low as possible. This minimizes the thickness of the top surface layer on the target wafer after bonding, thereby improving the thermal impedance of the high electron mobility transistor manufactured with the method according to the present disclosure.

According to example embodiments, providing the second donor III-N epitaxial layer corresponds to forming, on the donor wafer and between the first donor III-N layer and the donor dielectric layer, a second donor III-N epitaxial layer epitaxially grown as a N-polar layer.

This way, when the donor wafer is turned upside down to be bonded to the target wafer, the second donor III-N epitaxial layer bonded onto the target substrate is Ga-polar. The density of threading dislocations in the epitaxial III-N semiconductor layer stack grown on top of the top surface layer is thereby minimized.

For example, providing the second donor III-N epitaxial layer corresponds to epitaxially growing the second donor III-N epitaxial layer on top of the donor wafer and between the first donor III-N layer and the donor dielectric layer as a N-polar layer. Alternatively, providing the second donor III-N epitaxial layer corresponds to epitaxially growing the second donor III-N epitaxial layer on top of a temporary wafer as a Ga-polar layer and between a donor dielectric layer and a layer of the material of the first donor III-N layer, bonding the temporary wafer to the donor wafer and separating the temporary wafer and the donor wafer at the level of the layer of the material the first donor III-N layer, thereby forming the first donor III-N layer on the donor wafer, with the second donor III-N epitaxial layer on top of the first donor III-N layer and with the donor dielectric layer on top of the second donor III-N epitaxial layer.

According to example embodiments, forming the donor film comprises epitaxially growing the first donor III-N layer, and epitaxially growing the first donor III-N layer corresponds to epitaxially growing a first section and a second section of the first donor III-N layer and epitaxially growing a third donor III-N epitaxial layer between the first section and the second section of the first donor III-N layer; and wherein the donor wafer and the target wafer are separated by splitting the first section of the first donor III-N layer.

For example, forming the donor film comprises epitaxially growing the first donor III-N layer, and epitaxially growing the first donor III-N layer corresponds to epitaxially growing a first section and a second section of the first donor III-N layer on top of the sacrificial substrate and epitaxially growing a third donor III-N epitaxial layer between the first section and the second section of the first donor III-N layer on top of the sacrificial substrate. In this embodiment, the first donor III-N layer is, for example, epitaxially grown as a N-polar layer. Alternatively, providing the first donor III-N layer corresponds to epitaxially growing the first donor III-N layer on top of a temporary wafer as a Ga-polar layer, wherein the first donor III-N layer comprises a first section and a second section on top of the first section, bonding the temporary wafer to the donor wafer and separating the temporary wafer and the donor wafer at the level of the first section, thereby forming the first donor III-N layer on the donor wafer, wherein the second section of the temporary wafer becomes the first section of the first donor III-N layer on the donor wafer and wherein the first section of the temporary wafer becomes the second section of the first donor III-N layer on the donor wafer.

This way, the donor wafer and the target wafer are separated from each other by SMART CUT™ by causing the first section of the first donor III-N layer on the donor wafer to split, thereby leaving a first remaining portion of first section of the first donor III-N layer on the sacrificial substrate separated from the target substrate, and also leaving a second remaining portion of first section of the first donor III-N layer on the target substrate, wherein a sum of a thickness of the first remaining portion and of a thickness of the second remaining portion substantially corresponds to the total thickness of the first section of the first donor III-N layer grown on the sacrificial substrate prior to bonding. In other words, the first section of the first donor III-N layer is split within its thickness. This separation forms on the target wafer a top surface layer comprising at least partially the first section of the first donor III-N layer initially grown on the sacrificial substrate and bonded onto the target wafer, and comprising the third donor III-N epitaxial layer, and comprising the second section of the first donor III-N layer initially grown on the sacrificial substrate, wherein a thickness of the top surface layer on the target wafer is equal to or lower than 200 nm.

Additionally, the third donor III-N epitaxial layer can be used as an etch-stop for accurately and reliably controlling the thickness of the second section of the first donor III-N layer. Indeed, after bonding the donor film to the target wafer and after separating the donor wafer and the target wafer at the level of the first section of the first donor III-N layer, the first section of the first donor III-N layer is thinned down, for example, by chemical mechanical polishing, also referred to as CMP. This first section of the first donor III-N layer is thinned down until the third donor III-N epitaxial layer. The third donor III-N epitaxial layer can then be selected etched with respect to the underlying second section of the first donor III-N layer. For example, a wet etch using KOH can be used to selectively etch the AlN of the third donor III-N epitaxial layer without etching the GaN of the second section of the first donor III-N layer. This chemical etch of the third donor III-N epitaxial layer can therefore expose the second section of the first donor III-N layer. This way, the thickness of the second section of the first donor III-N layer remaining on the target substrate can be very accurately and reliably controlled in a simple manner. This allows to minimize the thickness of the second section of the first donor III-N layer on the target substrate by growing the desired thickness of the second section of the first donor III-N layer on the donor wafer.

According to example embodiments, the third donor III-N epitaxial layer comprises Aluminum Nitride.

The third donor III-N epitaxial layer, for example, comprises AlN. For example, the third donor III-N epitaxial layer comprises N-polar AlN epitaxially grown on top of the sacrificial substrate. This way, when the donor wafer is turned upside down and when the donor film is bonded to the target wafer, the third donor III-N epitaxial layer comprises Ga-polar AlN. The density of threading dislocations in the epitaxial III-N semiconductor layer stack grown on top of the top surface layer is thereby minimized.

According to example embodiments, providing a donor wafer further comprises providing a III-N buffer formed between the sacrificial substrate and the donor film.

A III-N buffer formed between the sacrificial substrate and the donor film, for example, comprises a Ga-polar epitaxially grown buffer. This way, the quality of the epitaxial growth of the first donor III-N layer is improved. A thickness of the III-N buffer is, for example, a few hundreds of nanometers, or a few micrometers. For example, the III-N buffer formed between the sacrificial substrate and the donor film, for example, comprises Ga-polar GaN. This way, the quality of the epitaxial growth of the first donor III-N layer is improved, for example, the quality of the epitaxial growth of N-polar GaN. Optionally, the donor wafer may further comprise a donor dielectric layer on top of the first donor III-N layer, wherein a thickness of donor dielectric layer is equal to or lower than 10 nm. Optionally, the donor film further comprises a second donor III-N epitaxial layer epitaxially grown between the first donor III-N layer and the donor dielectric layer, wherein the second donor III-N epitaxial layer, for example, comprises a N-polar material, such as, for example, N-polar AlN, and wherein a thickness of the second donor III-N epitaxial layer is equal to or lower than 10 nm.

The III-N buffer may be of a different nature than the sacrificial substrate, in that, for instance, the bandgap of the sacrificial substrate and III-N buffer are relatively far apart such as 1.1 eV and 6.2 eV, respectively, in the sense that the III-N buffer has a high bandgap, in order to provide present characteristics, such as high break down voltage, e.g., larger than 250 V, preferably larger than 500 V, even more preferably larger than 1000 V, such as larger than 2000 V, or even much larger. The III-N buffer is, for example, a III-N buffer with a high bandgap. Therein III refers to Group III elements, such as B, Al, Ga, In, Tl, Sc, Y and Lanthanide and Actinide series. The III-N buffer may comprise a stack of layers, in an example typically the first one on the sacrificial substrate being, for example, a nucleation layer.

According to example embodiments, the method further comprises the steps of:
after separating the donor wafer and the target wafer along the first donor III-N layer and prior to epitaxially growing the epitaxial III-N semiconductor layer stack, loading the target wafer comprising the top surface layer in an epitaxial chamber; and
desorbing the top surface layer in situ the epitaxial chamber.

The target wafer comprising the top surface layer is prepared for epitaxy, for example, the target wafer comprising the top surface layer is submitted to a chemical mechanical polishing to prepare the top surface layer for epitaxy. The target wafer comprising the top surface layer is loaded in an epitaxial chamber for growth of the epitaxial III-N semiconductor layer stack. The surface of the top surface layer is cleaned up by an in situ desorption step, thereby removing any surface or implantation damage. This way, the surface of the top surface layer is in pristine condition for epitaxially growing the epitaxial III-N semiconductor layer stack on top of the top surface layer in situ the epitaxial chamber. This improves the quality of the epitaxial growth of the active layers of the high electron mobility transistor, thereby improving the electrical and thermal characteristics of the high electron mobility transistor. In the context of the present disclosure, epitaxially growing is performed by MOCVD or MBE or any other suitable epitaxial chamber. The epitaxial layers of the donor wafer can be formed in situ by epitaxial growth in an MOCVD or an MBE epitaxial chamber. The first active III-N layer and the second active III-N layer can be formed in situ by epitaxial growth in an MOCVD or an MBE epitaxial chamber.

According to example embodiments, forming the donor film comprises epitaxially growing the first donor III-N layer on top of the sacrificial substrate, and epitaxially growing the first donor III-N layer corresponds to epitaxially growing the first donor III-N layer as a N-polar layer.

For example, forming the donor film comprises epitaxially growing the first donor III-N layer, and epitaxially growing the first donor III-N layer on top of the sacrificial substrate corresponds to epitaxially growing the first donor III-N layer as a N-polar layer on top of the sacrificial substrate.

The first donor III-N layer, for example, comprises N-polar GaN epitaxially grown on the donor wafer by MOCVD or by MBE. The donor wafer is turned upside-down, and the first donor III-N layer is bonded on the top side of the target wafer. The donor wafer and the target wafer are then bonded together. This way, the first donor III-N layer bonded on the top side of the target wafer is Ga-polar. The density of threading dislocations in the epitaxial III-N semiconductor layer stack grown on top of the top surface layer is thereby minimized.

According to example embodiments, forming the donor film comprises providing a first donor III-N layer. In this example embodiment, the material of a temporary first donor III-N layer is, for example, epitaxially grown on top of a temporary sacrificial substrate of a temporary wafer and the material of the temporary first donor III-N layer is epitaxially grown as a Ga-polar layer on the temporary sacrificial substrate of the temporary wafer. For example, the temporary first donor III-N layer comprises Ga-polar GaN epitaxially grown on the temporary sacrificial substrate. In this example embodiment, the method further comprises the following steps:
providing a temporary wafer comprising a temporary first donor III-N layer;
bonding the temporary first donor III-N layer to the donor wafer; and
separating the temporary wafer and the donor wafer by splitting the temporary first donor III-N layer, thereby forming on the donor wafer the first donor III-N layer at least partially comprising the temporary first donor III-N layer bonded onto the donor wafer.

The temporary wafer thus corresponds to a temporary donor wafer that further comprises a temporary sacrificial substrate and the temporary first donor III-N layer. As such, by the bonding, the temporary first donor III-N layer is bonded to the sacrificial substrate. Further, the separating may also be performed by separating the temporary wafer and the donor wafer at the interface between the temporary first donor III-N layer and the temporary sacrificial substrate.

This way, the layer transfer via SMART CUT™ is performed twice, sequentially. The first transfer starts with the temporary first donor III-N layer grown, for example, as a Ga-polar layer on the temporary wafer. This temporary first donor III-N layer grown as a Ga-polar layer is transferred to the donor wafer to form the first donor III-N layer as a N-polar layer on the donor wafer. A second SMART CUT™ transfer from this donor wafer to the target wafer is then performed, thereby flipping the material of the original temporary first donor III-N layer again, and thereby flipping the material of the first donor III-N layer, such that a Ga-polar surface of the material of the first donor III-N layer is formed as a top surface layer on the target wafer. With these extra method steps corresponding to a double layer transfer, there is, for example, no need to epitaxially grow the first donor III-N layer as a N-polar layer on top of the sacrificial substrate of the donor wafer. The quality of the first donor III-N layer on top of the sacrificial substrate is improved when it is epitaxially grown as a Ga-polar layer than when it is grown as a N-polar layer.

According to example embodiments, providing a temporary wafer corresponds to:
providing a temporary sacrificial substrate; and
epitaxially growing the temporary first donor III-N layer on top of the temporary sacrificial substrate;
or wherein the providing a temporary wafer corresponds to growing the temporary first donor III-N layer as a Ga-polar bulk III-N layer and bonding the temporary first donor III-N layer to the donor wafer corresponds to tiling the sacrificial substrate with one or more temporary wafers by bonding the temporary first donor III-N layers of the temporary wafers to the donor wafer.

This way, the donor film is obtained either by epitaxially growing the temporary first donor III-N layer on top of the temporary sacrificial substrate of the temporary wafer; or the donor film is obtained by tiling free-standing bulk III-N material on top of the sacrificial substrate. For example, the donor film is obtained from tiling of free-standing bulk GaN material on top of the sacrificial substrate. A thickness of the free-standing bulk III-N material of the temporary first donor III-N layer is, for example, a few hundreds of micrometers, such as, for example, 500 μm. In this example embodiment, the temporary wafers used for tiling are in general not epitaxially grown but fabricated using some bulk crystal growth method (although temporary wafers comprising a substrate onto which a III-N layer has been epitaxially grown may also be envisioned). The easiest approach would be to tile the bulk substrates on the sacrificial substrate of the donor wafer with the N-face up along the traverse direction 4 visible in the figures, and then SMART CUT™ them to the target wafer. As the temporary first donor III-N layer is, for example, a few hundreds of micrometers thick, the process of SMART CUT™ from the donor wafer, onto which the temporary first donor III-N layer is bonded, to the target wafer can be repeated more than once, with a refresh CMP of the temporary first donor III-N layer in between, thereby reducing processing costs. The temporary first donor III-N layer may, for example, be formed on top of a set of small substrates, for example, as a Ga-polar, and transferred onto a larger donor wafer, thereby, for example, forming a N-polar layer. This enables to create a donor wafer from III-N compatible substrates of one or more diameters smaller than the diameter of the donor wafer.

According to example embodiments, the first active III-N layer comprises gallium nitride and wherein a thickness of the first active III-N layer is equal to or lower than 50 nm.

Preferably, the first active III-N layer is grown epitaxially and comprises pure gallium nitride, preferably a monolayer of gallium nitride.

According to example embodiments, the first active III-N layer comprises InAlGaN, and the second active III-V layer comprises InAlGaN, and the second active III-N layer comprises a bandgap larger than a bandgap of the first active III-N layer and the second active III-N layer comprises a polarization larger than the polarization of the first active III-N layer.

This way, the use of different materials in adjacent first active III-N layer and second III-N layer causes polarization, which contributes to a conductive 2 DEG region near the junction between the first active III-N layer and the second active III-N layer, in particular, in the first active III-N layer, which comprises a bandgap narrower than the bandgap of the second active III-N layer.

According to example embodiments, the second active III-N layer comprises Indium Gallium Aluminum Nitride.

The second active III-N layer, for example, has a thickness comprised between 10 to 100 nm, preferably between 20 to 50 nm. Such a combination of thicknesses provides good characteristics for the active layer, for example, in terms of the 2 DEG obtained.

According to example embodiments, the epitaxial III-N semiconductor layer stack is adapted to host an electronic channel between the source region and the drain region when a positive bias voltage is applied to the gate contact.

This way, once a bias voltage is applied to the gate contact that is larger than the threshold voltage of the high electron mobility transistor, electrons flow in the electronic channel under the gate between the source and the drain of the high electron mobility transistor.

According to example embodiments, the method further comprises the steps of:
forming a source contact contacting the second active III-N layer in a source region; and
forming a drain contact contacting the second active III-N layer in a drain region.

Preferably, the source contact and/or the drain contact are ohmic contacts formed respectively in a source region and/or in a drain region.

The source and the drain contacts are ohmic contacts to the 2 DEG and can be made by depositing metal stacks, such as, for example, Ti/Al/Ni/Au, Ti/Al/Mo/Au, Ti/Al/Ti/Au, Ti/Al/Ti/W, Ti/Al/W, Ti/Al/W/Cr, Ta/Al/Ta, V/Al/Ni/Au, etc., in contact with the second active III-N layer of the epitaxial III-N semiconductor layer stack. The second active III-N layer may be recessed prior to metal deposition. The contact properties may be further improved by thermal annealing, typically at a temperature comprised between 800° C. and 900° C., such as, for example, 850° C., in a nitrogen atmosphere or a forming gas atmosphere. Alternatively, additional metal interconnect layers are defined using methods known to a person skilled in the art, to allow low resistivity current pathways for the gate, source and drain currents.

Forming an ohmic contact in the source region and forming an ohmic contact in the drain region comprise plurality of process steps. For example, this is done by starting with depositing photoresist and defining the respective areas of the respective ohmic contacts with a lithography step. Potential passivation layers are then partially or fully removed respectively in a source region and/or in a drain region. Alternatively, potential passivation layers are fully removed in a source region and/or in a drain region. Once the areas of the ohmic contacts are defined, i.e., when the source region and the drain region have been defined, a metal layer or a stack of metal layers can be deposited, for example, by thermal evaporation, or by sputtering, or by e-beam evaporation. Metal patterns are consecutively defined by performing lift-off of the metal, on top of the photoresist and not in contact with the second active III-N layer. Alternatively, the photoresist is first removed and the metal stack comprising, for example, Ti and Al is deposited and then a second photoresist deposition and photolithography steps are performed to allow dry etching of the metal stack in areas where it is unwanted and removing the photoresist. The defined ohmic contacts may then be subjected to one or more alloying steps, for example, a rapid thermal annealing step for a duration of one minute in a reduced or inert atmosphere such as, for example, hydrogen or forming gas or nitrogen gas at a temperature, for example, between 800° C. and 900° C.

According to example embodiments, the method further comprises the steps of:
etching the epitaxial III-N semiconductor layer stack away in one or more regions;
in the one or more regions, forming one or more recesses extending through the top surface layer until at least partially into the target substrate, wherein the one or more recesses are not positioned between the gate region and the source region or between the gate region and the drain region, thereby defining one or more electrical isolation regions;
providing a dielectric layer in one or more of the recesses; and
forming a contact in the one or more electrical isolation regions on top of the dielectric layer, thereby forming one or more electrical isolations.

The one or more recesses extending through the top surface layer until at least partially into the target substrate may extend, for example, through the III-N buffer and at least partially through the target substrate. For example, this allows the combination between a SOI target substrate and the deep trench etching of the electrical isolations described above to create electrically isolated islands with varying substrate bias.

According to example embodiments, the method further comprises the steps of providing a passivation stack on top of the second active III-N layer.

Providing the passivation stack on top of the epitaxial III-N semiconductor layer stack corresponds to epitaxially growing the passivation stack on top of the epitaxial III-N semiconductor layer stack.

The passivation stack is, for example, formed in situ with the formation of the epitaxial III-N semiconductor layer stack. The passivation stack is, for example, formed on top of the second active III-N layer. This way, a fully crystalline passivation stack is epitaxially grown on top of the epitaxial III-N semiconductor layer stack. Alternatively, a partially crystalline passivation stack is epitaxially grown on top of the epitaxial III-N semiconductor layer stack. The passivation stack may also be formed by ex-situ deposition with the help of epitaxy tools like atomic layer deposition, also referred to as ALD, chemical vapor deposition, also referred to as CVD, or physical vapor deposition, also referred to as PVD. Alternatively, the passivation stack may be formed by in situ deposition in an MOCVD or an MBE chamber. Alternatively, the passivation stack may be formed by depositing an amorphous film of the same material and recrystallizing it using thermal anneal. The passivation stack on top of the second active III-N layer, for example, comprises silicon nitride. Alternatively, the passivation stack on top of the second active III-N layer, for example, comprises gallium nitride. Alternatively, the passivation stack on top of the second active III-N layer comprises gallium nitride and silicon nitride.

A passivation stack is formed between the epitaxial III-N semiconductor layer stack and, for example, a gate of a transistor. The passivation stack may be formed only under the gate and may serve additionally as gate dielectric. Alternatively, the passivation stack may be formed on top of the epitaxial III-N semiconductor layer stack and may fully cover the epitaxial III-N semiconductor layer stack. Alternatively, the passivation stack may be formed on top of the epitaxial III-N semiconductor layer stack and partially cover the surface of the epitaxial III-N semiconductor layer stack, for example, it may be formed in the ungated area between the source and the drain of a high mobility electron transistor, where it serves as passivation and prevents the depletion of the underlying 2 DEG.

According to example embodiments, the passivation stack further comprises an oxide layer and/or silicon nitride.

This way, the passivation stack comprises silicon nitride and/or an oxide layer that acts as a passivation layer. The oxide layer exhibits an electrically clean interface to the second active III-N layer, a high dielectric constant to maximize electrostatic coupling between electrical contacts formed onto the semiconductor structure and the 2 DEG that results in an increase of, for example, the transconductance of high electron mobility transistors manufactured with the semiconductor structure and a sufficient thickness to avoid dielectric breakdown and leakage by quantum tunneling.

The passivation stack comprises, for example, SiN with a high density, deposited in situ in an MOCVD reactor. The SiN may be stochiometric or non-stochiometric. It has been shown experimentally that, for example, a HEMT structure that is capped with in situ SiN is not affected by processing steps, even those that have a high temperature budget. Alternatively, the passivation stack comprises, for example, AlSiN. The Al-doping allows increasing the bandgap of the dielectric material. Alternatively, the electron donating dielectric layer comprises one or more of Si, Al, O and N. The passivation stack has, for example, a thickness of 1 to 500 nm, preferably 30 to 400 nm, more preferably 50 to 300 nm, such as 100 to 200 nm. The in situ SiN may be thickened externally by PECVD or LPCVD SiN or SiOx, for example, for thicknesses beyond 500 nm, before any other processing takes place. A thin passivation stack allows the formation of ohmic contacts with a low resistance. Additionally, the passivation stack comprises, for example, Si, which can diffuse in the AlGaN where it acts as a donor. The introduction of a donor type in the AlGaN layer facilitates the ohmic contact formation reducing thereby the contact resistance. The passivation stack is formed at a temperature between 700° C. and 1300° C., between 700° C. and 1250° C., between 700° C. and 1100° C. It should be understood that when SiN is mentioned, a compound consisting of Si and N is meant. SiN can include Si₃N₄, but also other formulas are included, such as, but not limited hereto, SiₓN_{y}, being in different stochiometric or non-stochiometric ratios. In the formula SiₓN_{y}, x and y can be defined as real numbers, with 0<x≤100 and 0<y≤100. When the epitaxial III-N semiconductor layer stack is grown, NH₃ is kept flowing in the reaction chamber and the SiH₄ line is opened, allowing for growth of SiN and high temperature. After growth of SiN, the SiH₄ flow is stopped and the structure is cooled down to room temperature while keeping the NH₃ flow, to avoid desorption from the top layer.

According to example embodiments, the passivation stack is epitaxially grown on top of the second active III-N layer.

It is an advantage that the crystallinity of in situ grown SiN is maintained by doping it or adding a species such as Al or B. When grown on top of the second active III-N layer, the in situ SiN deforms to accommodate to the strain resulting from the lattice mismatch between the materials. It is well known that large lattice mismatch is a trigger to revert the epitaxial growth mode from a two-dimensional Franck-Van der Merwe layer-by-layer growth mode into a three-dimensional Volker-Weber growth mode, which is then in turn more prone to turn into an amorphous growth mode. A smaller atom than Si can thus be incorporated into the SiN, for example, Al or B, to shrink the lattice constant of the beta-phase SiN and match it better to the lattice constant of the second active III-N layer. An additional advantage of the inclusion of Al in the SiN lattice is an improved resistance to dry etching in fluorine-based plasmas because of the interaction between Al and F, which yields highly involatile AIF. The passivation stack is fully crystalline. Alternatively, the passivation stack is partially crystalline and comprises at least a few crystalline monolayers.

According to example embodiments, the passivation stack is etched away respectively in a source region and a drain region.

This way, openings are defined in the electron donating dielectric layers to uncover respectively a source region and a drain region in which the device terminals are to be formed. For example, a photolithography step may be performed and the electron donating dielectric layers may be etched away respectively in a source region and in a drain region. For example, the passivation stack can be removed by wet etching in HF or buffered HF or by dry etching in a RIE or ICP plasma tool in a fluorine chemistry.

Both dry and wet etches of the passivation stack in a fluorine chemistry will stop on the second active III-N layer, which acts as an etch-stop with very high selectivity. For example, the etch of the electron donating dielectric layers is done in a dry etching system based on fluorine chemistry such as, for example, in an inductively coupled plasma system using SF₆ or CF₄ as etching gas and RF, or “platen,” and ICP, or “coil” etching powers of 10 W to 150 W, respectively. This allows for thorough removal of the remaining passivation stack without removing the second active III-N layer or any of the layers below. Alternatively, the second active III-N layer is partially etched in a wet etch, for example, in an alkaline solution or in resist developer, thereby allowing to form respective ohmic contacts in a source region and in a drain region partly in the active layer.

According to a second aspect of the present disclosure, there is provided a high electron mobility transistor comprising:
a target substrate;
a top surface layer on top of the target substrate; wherein a thickness of the top surface layer is less than 200 nm;
an epitaxial III-N semiconductor layer stack on top of the top surface layer, wherein the epitaxial III-N semiconductor layer stack comprises:
   a first active III-N layer;
   a second active III-N layer on top of the first active III-N layer;
   with a two-dimensional Electron gas between the first active III-N layer and the second active III-N layer;
a gate contact contacting the second active III-N layer in a gate region; and
a substrate galvanic contact contacting the target substrate.

The high electron mobility transistor according to the present disclosure can be formed on any substrate, even, for example, foreign substrates. The high electron mobility transistor according to the present disclosure is formed from an epitaxial III-N semiconductor layer stack grown on top of a top surface layer bonded onto, i.e., transferred onto by SMART CUT™, for example, a silicon substrate, such as, for example, a high-resistive silicon substrate, or a SiC substrate, such as, for example, a semi-insulating SiC substrate, or a Silicon-On-Insulator substrate, or a germanium substrate, or a germanium-on-insulator substrate, or a sapphire substrate, etc. Additionally, the donor film is bonded to the target wafer without having to provide a buffer layer on the target wafer between the substrate and the high electron mobility transistor prior to bonding. In other words, a buffer layer must not be grown onto the target substrate prior to bonding the donor film onto the target substrate. The high electron mobility transistors according to the present disclosure are therefore less prone to trapping effects than prior art high electron mobility transistors grown, for example, on semi-insulating SiC substrates or on high-resistive Si substrates.

Another advantage of the high electron mobility transistor according to the present disclosure is its improved thermal impedance. Thanks to the lack of buffer layers between the epitaxial III-N semiconductor layer stack and the target substrate, and thanks to the thickness of the transferred first donor III-N layer forming the top surface layer, which is kept as thin as possible, and thanks to the limited thickness of the total layer stack formed on the target substrate, low thermal resistivity can be achieved for the high electron mobility transistor. In other words, there is less thermal impedance between the heat sink at the bottom of the target substrate and the active device such as, for example, the high electron mobility transistor manufactured according to the present disclosure. The thickness of the top surface layer is kept as low as possible, and this layer is maximum 200 nm thick, preferably less than 100 nm thick, preferably less than 50 nm thick.

An additional advantage of the high electron mobility transistor according to the present disclosure is that the thin layer stack formed on top of the target substrate enables the use of the substrate as a fourth terminal for the high electron mobility transistor. This way, the substrate galvanic contact contacting the target substrate can indeed be used to impose a bottom side voltage bias on the target substrate relative to the source contact of the high electron mobility transistor. Thanks to the low thickness of the layers between the bottom side of the target substrate and the 2 DEG, this substrate galvanic contact can in turn be used to control or change certain properties or parameters of the high electron mobility transistor, such as, for example, the threshold voltage and/or the off-state leakage of the high electron mobility transistor. The substrate galvanic contact can also be used to modulate, for example, the charging state of the buffer or bulk traps present in the target substrate, thereby minimizing or eliminating trapping effects of the high electron mobility transistor, and thereby reducing memory effects in the high electron mobility transistor. The substrate galvanic contact may be formed on the bottom side of the target substrate and substantially below a gate region of the high electron mobility transistor manufactured on the target wafer after bonding and epitaxial growth of the epitaxial III-N semiconductor layer stack. Alternatively, the substrate galvanic contact may be formed on the bottom side of the target substrate and substantially below the high electron mobility transistor manufactured on the target wafer after bonding and epitaxial growth of the epitaxial III-N semiconductor layer stack.

According to example embodiments, the HEMT further comprises a dielectric layer stack formed between the target substrate and the top surface layer; and wherein a thickness of the dielectric layer stack is equal to or lower than 60 nm.

According to example embodiments, the HEMT further comprises a second donor III-N epitaxial layer formed between the dielectric layer stack and the top surface layer; and wherein a thickness of the second donor III-N epitaxial layer is equal to or lower than 10 nm.

### BRIEF DESCRIPTION OF THE DRAWINGS

Some example embodiments will now be described with reference to the accompanying drawings. The drawings depict cross-sections of wafers and high electron mobility transistors according to the present disclosure for clarity reasons. It is clear that the wafers and the high electron mobility transistors depicted in the accompanying drawings can have any shape and extend along any direction along the longitudinal direction 3 and/or the traverse direction 4, and/or a third direction 5 traverse to the longitudinal direction 3 and traverse to the traverse direction 4. The above directions are not repeated on all the accompanying drawings to keep the drawings simple.

FIGS. 1A-1J schematically depict an example embodiment of the steps of the method of manufacturing a high electron mobility transistor according to the present disclosure, wherein FIG. 1J schematically depicts an example embodiment of a high electron mobility transistor according to the present disclosure. FIG. 1K illustrates an alternative embodiment for the manufacturing step as illustrated in FIG. 1F.

FIG. 2 schematically depicts an example embodiment of a target wafer according to the present disclosure.

FIG. 3A schematically depicts an example embodiment of a donor wafer according to the present disclosure. FIG. 3B schematically depicts an example embodiment of a target wafer according to the present disclosure after bonding of the donor wafer according to the present disclosure and depicted in FIG. 3A.

FIG. 4 schematically depicts an example embodiment of a target wafer according to the present disclosure after bonding.

FIG. 5 schematically depicts an example embodiment of a donor wafer according to the present disclosure.

FIG. 6 schematically depicts an example embodiment of a donor wafer according to the present disclosure.

FIG. 7 schematically depicts an example embodiment of a donor wafer according to the present disclosure.

FIGS. 8A-8H schematically depict an example embodiment of the steps of the method of manufacturing a high electron mobility transistor from a donor wafer according to the present disclosure. FIG. 8I illustrates an alternative embodiment for the manufacturing step as illustrated in FIG. 8F.

FIG. 9 schematically depicts an example embodiment of a high electron mobility transistor according to the present disclosure, with a source contact and a drain contact.

FIG. 10 schematically depicts an example embodiment of a high electron mobility transistor according to the present disclosure, with electrical isolations.

### DETAILED DESCRIPTION

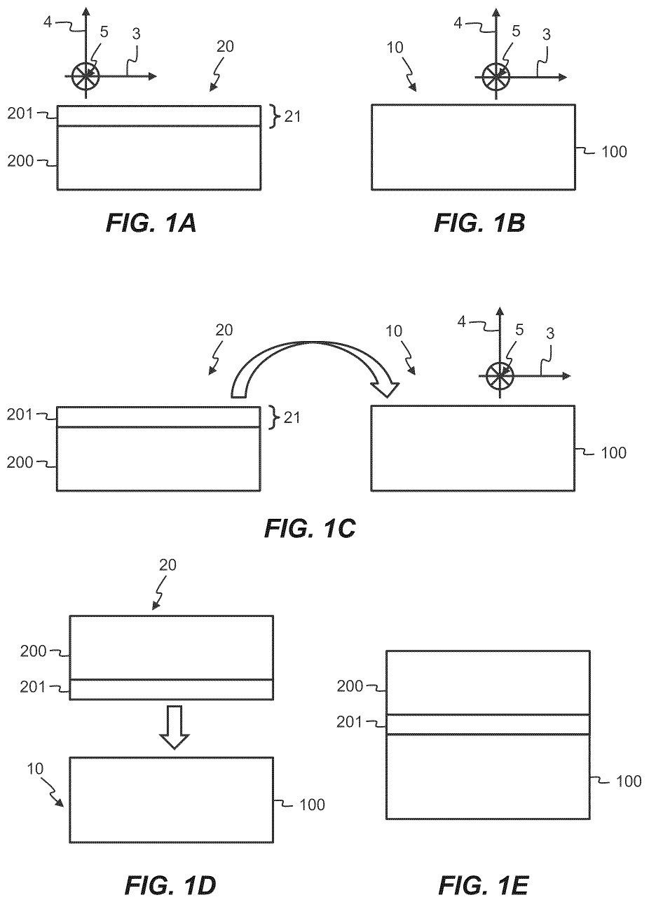

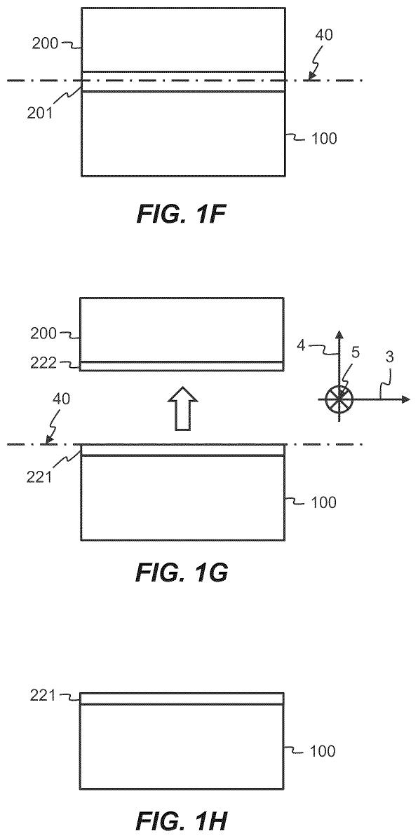

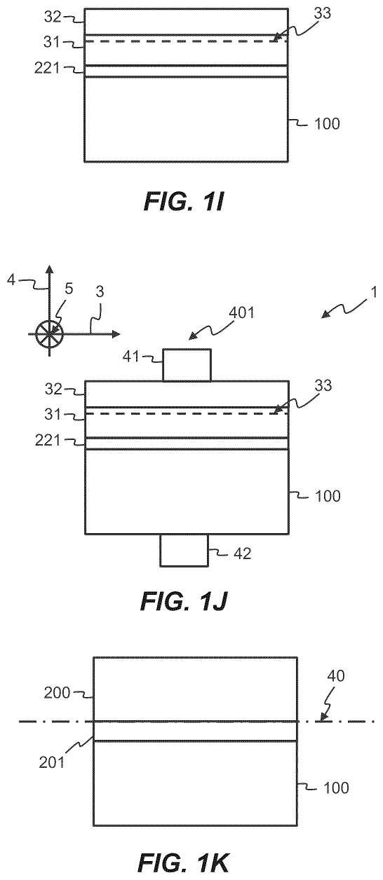

FIGS. 1A-1J schematically depict an example embodiment of the steps of the method of manufacturing a high electron mobility transistor 1 (FIG. 1J) according to the present disclosure. A donor wafer 20 is provided, as visible in FIG. 1A. The donor wafer 20 comprises a sacrificial substrate 200. On top of the sacrificial substrate 200, a donor film 21 is formed. The donor film 21 comprises a first donor III-N layer 201. The first donor III-N layer 201 is, for example, epitaxially grown on top of the sacrificial substrate 200. A target wafer 10 comprising a target substrate 100 is also provided, as visible in FIG. 1B. In FIG. 1C, the donor wafer 20 is flipped upside down with respect to its initial orientation and with respect to the target wafer 10. The flipped donor wafer 20 is then lowered toward the target wafer 10 as shown in FIG. 1D. FIG. 1E shows the donor film 201 bonded to the target wafer 10. The donor wafer 20 and the target wafer 10 are separated from each other using the SMART CUT™ technology along the plane 40 visible in FIG. 1F. The donor wafer 20 and the target wafer 10 are separated by splitting the first donor III-N layer 201 at the level of the plane 40, thereby forming on the target wafer 10 a top surface layer 221 comprising at least partially the first donor III-N layer 201 bonded onto the target wafer 10, and also forming on the donor wafer 20 a donor surface layer 222 comprising at least partially the first donor III-N layer 201 epitaxially grown on the donor wafer 20, as visible in FIG. 1G. A thickness of the top surface layer 221 is equal to or lower than 200 nm. Additionally, a sum of the thickness of the top surface layer 221 and of the thickness of the donor surface layer 222 substantially corresponds to the thickness of the first donor III-N layer 201 epitaxially grown on the donor wafer 20. According to an alternative embodiment as shown in FIG. 1K, the donor wafer 20 and the target wafer 10 are separated at the interface 40 between the first donor III-N layer 201 and the sacrificial substrate 200, thereby forming on the target wafer 10 a top surface layer 221 comprising the first donor III-N layer 201 bonded onto the target wafer 10. In this alternative embodiment, a thickness of the top surface layer 221 is equal to or lower than 200 nm, and substantially corresponds to the thickness of the first donor III-N layer 201 epitaxially grown on the donor wafer 20. The method according to the present disclosure therefore results in the semiconductor structure depicted in FIG. 1H, with a top surface layer 221 formed on the target substrate 100 of the target wafer 10. FIG. 1I shows the following method step of epitaxially growing an epitaxial III-N semiconductor layer stack 300 on top of the top surface layer 221, wherein the epitaxial III-N semiconductor layer stack 300 comprises a first active III-N layer 31 and a second active III-N layer 32, with a two-dimensional Electron gas 33 between the first active III-N layer 31 and the second active III-N layer 32. As shown in FIG. 1J, the method further comprises the steps of forming a gate contact contacting the second active III-N layer 32 in a gate region 401 and forming a substrate galvanic contact 42 contacting the back side of the target substrate 100 along the traverse direction 4. A high electron mobility transistor 1 has been manufactured.

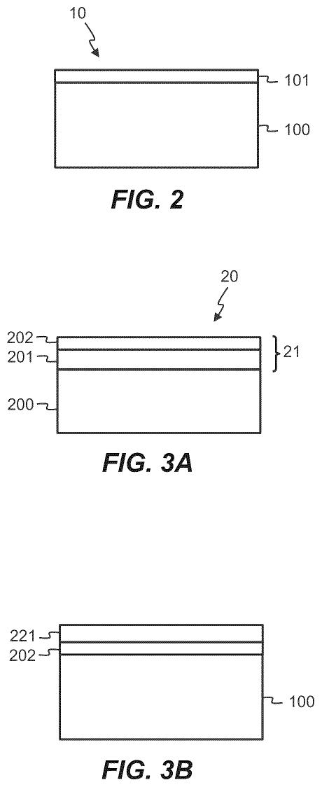

FIG. 2 schematically shows an example embodiment of a target wafer 10 according to the present disclosure. Components having identical reference numbers in FIGS. 1A-1J fulfill the same function. Providing the target wafer 10 may further comprise forming a target dielectric layer 101 on top of the target substrate 100. A thickness of the target dielectric layer 101 is equal to or lower than 50 nm. With this target wafer 10, the donor film 201 of the donor wafer 20 is bonded to the target dielectric layer 101 of the target wafer 10.

FIG. 3A schematically depicts an example embodiment of a donor wafer 20 according to the present disclosure. Components having identical reference numbers in FIGS. 1A-1J or FIG. 2 fulfill the same function. Forming the donor film 201 further comprises forming a donor dielectric layer 202 on top of the first donor III-N layer 201. A thickness of the donor dielectric layer 202 is equal to or lower than 10 nm. The donor wafer 20 of FIG. 3A is then flipped upside down before being bonded to a target wafer 10. FIG. 3B schematically depicts an example embodiment of a target wafer 10 according to the present disclosure after bonding of the donor wafer 20 according to the present disclosure and depicted in FIG. 3A to the target wafer 10 of FIG. 1B. FIG. 3B shows a target substrate 100 onto which the donor dielectric layer 202 and the top surface layer 221 are bonded. The top surface layer 221 is formed after splitting the first donor III-N layer 201 to separate the donor wafer 20 and the target wafer 10. According to an alternative embodiment, the donor wafer 20, according to the present disclosure and depicted in FIG. 3A, could be bonded to the target wafer 10 of FIG. 2.

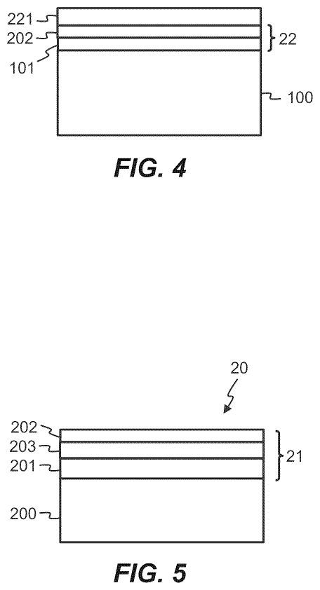

FIG. 4 schematically depicts an example embodiment of a target wafer according to the present disclosure after bonding. Components having identical reference numbers in FIGS. 1A-1J or FIGS. 2-3B fulfill the same function. Forming a donor film further comprises forming a donor dielectric layer 202 on top of the first donor III-N layer of a donor wafer. A thickness of the donor dielectric layer 202 is equal to or lower than 10 nm. The donor wafer is then flipped upside down before being bonded to a target wafer comprising a target substrate 100 onto which a target dielectric layer 101 is formed. A thickness of the target dielectric layer 101 is equal to or lower than 50 nm. FIG. 4 schematically depicts the target wafer after bonding the donor wafer to the target wafer. The donor dielectric layer 202 and the top surface layer 221 are bonded to the target dielectric layer 101, thereby forming a dielectric layer stack 22 comprising the target dielectric layer 101 and the donor dielectric layer 202. A thickness of the dielectric layer stack 22 is equal to or lower than 60 nm. The top surface layer 221 is formed after splitting the first donor III-N layer 201 to separate the donor wafer and the target wafer.

FIG. 5 schematically depicts an example embodiment of a donor wafer 20 according to the present disclosure. Components having identical reference numbers in FIGS. 1A-1J or FIGS. 2-4 fulfill the same function. The target wafer 10 comprises a sacrificial substrate 200 onto which a donor film 21 is formed. The donor film 21 comprises a first donor III-N layer 201 and a donor dielectric layer 202 on top of the first donor III-N layer 201. A thickness of the donor dielectric layer 202 is equal to or lower than 10 nm. The donor film 21 further comprises a second donor epitaxial layer 203 provided between the first donor III-N layer 201 and the donor dielectric layer 202. The second donor epitaxial layer 203 is epitaxially grown between the first donor III-N layer 201 and the donor dielectric layer 202. For example, the second donor epitaxial layer 203 is epitaxially grown as an N-polar layer between the first donor III-N layer 201 and the donor dielectric layer 202. A thickness of the second donor epitaxial layer 203 is equal to or lower than 10 nm.

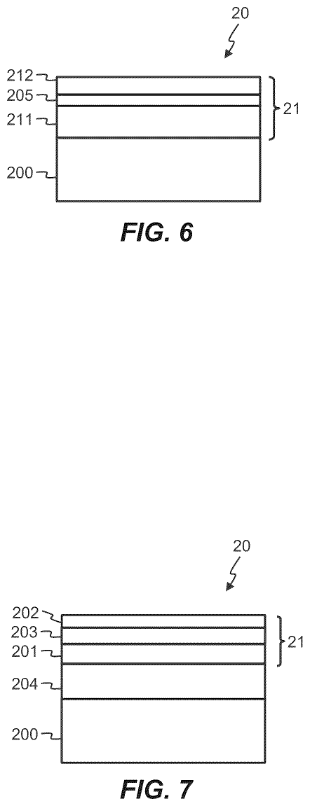

FIG. 6 schematically depicts an example embodiment of a donor wafer 20 according to the present disclosure. Components having identical reference numbers in FIGS. 1A-1J or FIGS. 2-5 fulfill the same function. The donor wafer 20 of FIG. 6 comprises a sacrificial substrate 200. A donor film 21 is formed on top of the sacrificial substrate 200 of the donor wafer 20. Forming the donor film 21 comprises epitaxially growing the first donor III-N layer 201, and wherein epitaxially growing the first donor III-N layer 201 corresponds to epitaxially growing a first section 211 and a second section 212 of the first donor III-N layer 201, for example, on top of the sacrificial substrate 200 and epitaxially growing a third donor III-N epitaxial layer 205 between the first section 211 and the second section 212 of the first donor III-N layer 201. The donor wafer 20 and the target wafer are then separated by splitting the first section 211 of the first donor III-N layer 201 and the third donor III-N epitaxial layer 205 acts as a etch stop to the second section 212 of the first donor III-N layer 201, thereby forming the top surface layer on top of the target wafer, wherein the top surface layer comprises the second section 212 of the first donor III-N layer 201 after removal of the third donor III-N epitaxial layer 205. The third donor III-N epitaxial layer 205, for example, comprises AlN.

FIG. 7 schematically depicts an example embodiment of a donor wafer 20 according to the present disclosure. Components having identical reference numbers in FIG. 1A_1J or FIGS. 2-6 fulfill the same function. The donor wafer 20 comprises a sacrificial substrate 200 onto which a III-N buffer 204 is provided. In other words, the III-N buffer 204 is formed between the sacrificial substrate 200 and the donor film 21 of the donor wafer 20. The donor film 21, for example, comprises a first donor III-N layer 201. According to an alternative embodiment, the donor film 21, for example, comprises a first donor III-N layer 201 and a donor dielectric layer 202. According to a further alternative embodiment, the donor film 21, for example, comprises a first donor III-N layer 201, a donor dielectric layer 202 and a second donor epitaxial layer 203 provided between the first donor III-N layer 201 and the donor dielectric layer 202.

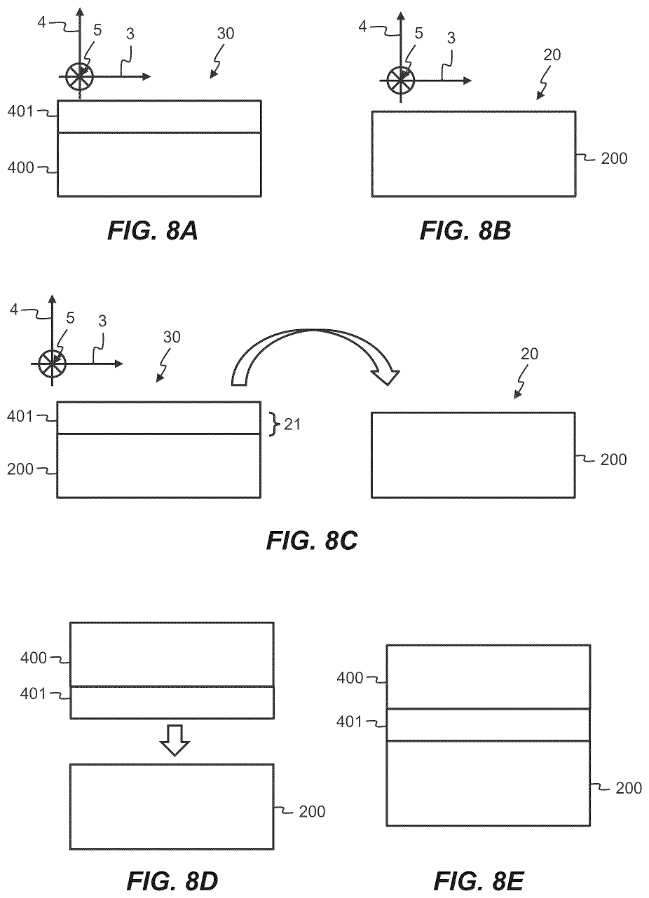

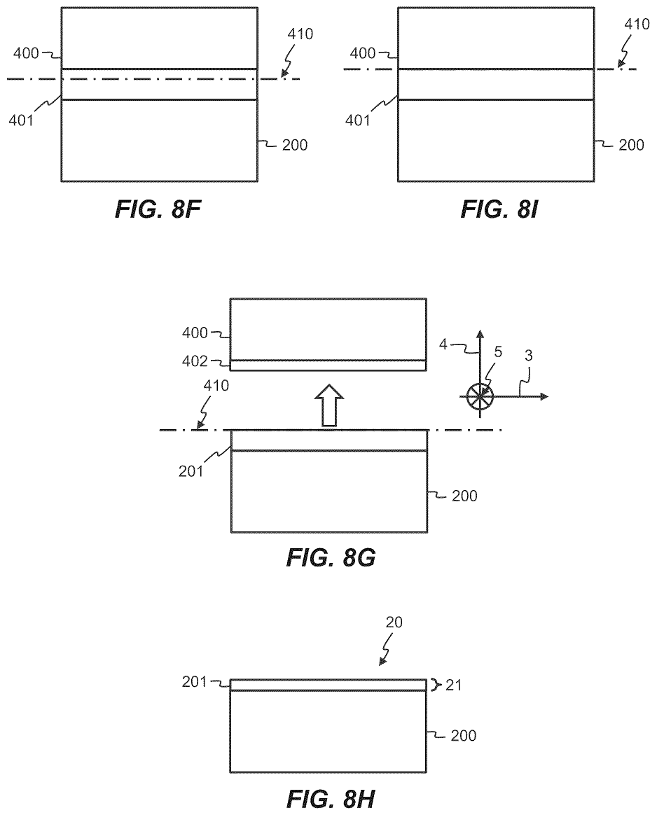

FIGS. 8A-8H schematically depict an example embodiment of the steps of the method of manufacturing a high electron mobility transistor from a donor wafer 20 according to the present disclosure. Components having identical reference numbers in FIGS. 1A-1J or FIGS. 2-7 fulfill the same function. A temporary donor wafer 30 is provided, as visible in FIG. 8A. In this example embodiment, the temporary donor wafer 30 comprises a temporary sacrificial substrate 400. A temporary first donor III-N layer 401 is epitaxially grown on top of the temporary sacrificial substrate 400, as visible in FIG. 8A. A donor wafer 20 is provided, wherein the donor wafer 20, for example, comprises a sacrificial substrate 200. According to an alternative embodiment, the donor wafer 20, for example, comprises a sacrificial substrate 200 and further comprises a dielectric layer on top of the sacrificial layer, wherein a thickness of the dielectric layer is equal to or lower than 50 nm and wherein the dielectric layer facilitates the bonding. The temporary first donor III-N layer 401 is flipped upside down with respect to the donor wafer 20 and with respect to its original orientation, as visible in FIG. 8C. The temporary first donor III-N layer 401 is bonded to the donor wafer 20, for example, directly to the sacrificial substrate 200 as shown in FIG. 8D, or alternatively to the dielectric layer formed on the sacrificial substrate 200. The temporary donor wafer 30 and the donor wafer 20 are separated by splitting the temporary first donor III-N layer 401 at the level of the plane 410, thereby forming on the donor wafer 20 the first donor III-N layer 201 at least partially comprising the temporary first donor III-N layer 401 bonded onto the donor wafer 20. According to a further embodiment as shown in FIG. 8I, the temporary donor wafer 30 and the donor wafer 20 are separated at the interface 410 between the temporary first donor III-N layer 401 and the temporary sacrificial substrate 400, thereby forming on the donor wafer 20 the first donor III-N layer 201 comprising the temporary first donor III-N layer 401 bonded onto the donor wafer 20. According to a further alternative embodiment, the temporary donor wafer 30 corresponds to a temporary first donor III-N layer 401 grown, for example, as a Ga-polar bulk III-N layer. The temporary first donor III-N layer 401 is then bonded to the donor wafer 20. For example, one or more temporary donor wafers 30 are bonded to the donor wafer 20, wherein a diameter of the donor wafer 20 is larger than a diameter of the temporary donor wafers 30. The donor wafer 20, for example, comprises a sacrificial substrate 200. According to an alternative embodiment, the donor wafer 20, for example, comprises a sacrificial substrate 200 and further comprises a dielectric layer on top of the sacrificial layer, wherein a thickness of the dielectric layer is equal to or lower than 50 nm and wherein the dielectric layer facilitates the bonding. The temporary first donor III-N layer 401 is flipped upside down with respect to the donor wafer 20 and with respect to its original orientation, as visible in FIG. 8C. The temporary first donor III-N layer 401 is bonded to the donor wafer 20, for example, directly to the sacrificial substrate 200 as shown in FIG. 8D, or alternatively to the dielectric layer formed on the sacrificial substrate 200. The temporary donor wafer 30 and the donor wafer 20 are separated by splitting the temporary first donor III-N layer 401 at the level of the plane 410, thereby forming on the donor wafer 20 the first donor III-N layer 201 at least partially comprising the temporary first donor III-N layer 401 bonded onto the donor wafer 20. The donor film 21 comprising the first donor III-N layer 201 is then bonded to a target wafer, for example, the target wafer of FIG. 1B, and the method steps as depicted in FIGS. 1C-1J are applied using the donor wafer 20 and the target wafer.

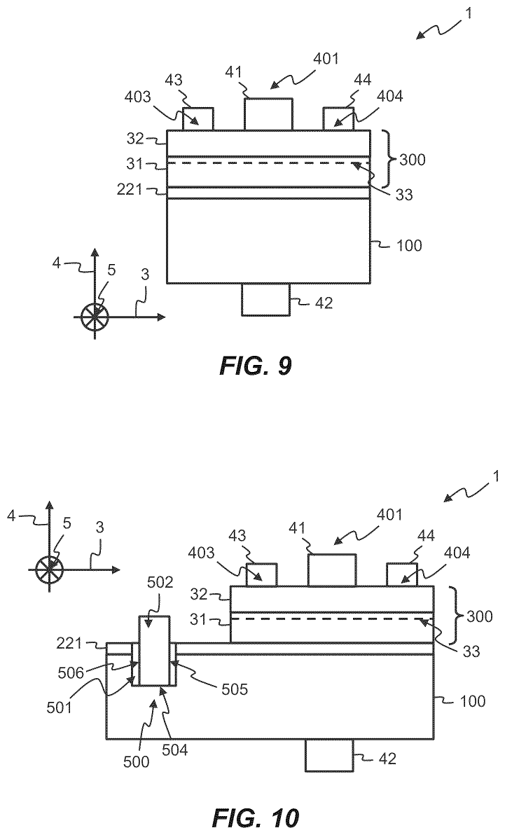

FIG. 9 schematically depicts an example embodiment of a high electron mobility transistor 1 according to the present disclosure, with a source contact 43 and a drain contact 44. Components having identical reference numbers in FIGS. 1A-1J or FIGS. 2-7 fulfill the same function. The method depicted in FIGS. 1A-1J further comprises the steps of forming a source contact 43 contacting the second active III-N layer 32 in a source region 403 and forming a drain contact 44 contacting the second active III-N layer 32 in a drain region 404.

FIG. 10 schematically depicts an example embodiment of a high electron mobility transistor 1 according to the present disclosure, with electrical isolations. Components having identical reference numbers in FIGS. 1A-1J or FIGS. 2-7 fulfill the same function. The method depicted in FIGS. 1A-1J further comprises the steps of forming a source contact 43 contacting the second active III-N layer 32 in a source region 403 and forming a drain contact 44 contacting the second active III-N layer 32 in a drain region 404 for the high electron mobility transistor 1 manufactured with the method according to the present disclosure. The method further comprises the step of etching the epitaxial III-N semiconductor layer stack 300 away in one or more electrical isolation regions. The method further comprises the step of forming one or more recesses 500 extending through the top surface layer 221 until at least partially into the target substrate 100, wherein the one or more recesses 500 are not positioned between the gate region 401 and the source region 403 or between the gate region 401 and the drain region 404, thereby defining one or more electrical isolation regions. The method further comprises the step of providing a dielectric layer 501 along the sidewalls 505, 506 of one or more of the recesses 500. The method further comprises the step of forming a contact 502 in the one or more electrical isolation regions such that the contact 502 is in direct contact with the target substrate 100 at the bottom 504 of each of the recesses 500 along the traverse direction 4 and such that the contact 502 is in contact with the dielectric layer 501 along the sidewalls 505, 506 of each of the recesses 500, thereby forming one or more electrical isolations.

Although the present disclosure has been illustrated by reference to specific embodiments, it will be apparent to those skilled in the art that the present disclosure is not limited to the details of the foregoing illustrative embodiments, and that the present disclosure may be embodied with various changes and modifications without departing from the scope thereof. The present embodiments are therefore to be considered in all respects as illustrative and not restrictive, the scope of the invention being indicated by the appended claims rather than by the foregoing description, and all changes that come within the scope of the claims are therefore intended to be embraced therein.

It will furthermore be understood by the reader of this disclosure that the words “comprising” or “comprise” do not exclude other elements or steps, that the words “a” or “an” do not exclude a plurality, and that a single element, such as a computer system, a processor, or another integrated unit may fulfil the functions of several means recited in the claims. Any reference signs in the claims shall not be construed as limiting the respective claims concerned. The terms “first,” “second,” “third,” “a,” “b,” “c,” and the like, when used in the description or in the claims are introduced to distinguish between similar elements or steps and are not necessarily describing a sequential or chronological order. Similarly, the terms “top,” “bottom,” “over,” “under,” and the like are introduced for descriptive purposes and not necessarily to denote relative positions. It is to be understood that the terms so used are interchangeable under appropriate circumstances and embodiments of the invention can operate according to the present disclosure in other sequences, or in orientations different from the one(s) described or illustrated above.

1. A method of manufacturing a high electron mobility transistor, the method comprising:
providing a target wafer comprising a target substrate;
providing a donor wafer, wherein providing the donor wafer comprises:
providing a sacrificial substrate; and
forming a donor film on top of the sacrificial substrate, wherein the donor film comprises a first donor III-N layer;
bonding the donor film to the target wafer;
separating the donor wafer and the target wafer by splitting the first donor III-N layer, or separating the donor wafer and the target wafer at the interface between the first donor III-N layer and the sacrificial substrate, thereby forming on the target wafer a top surface layer at least partially comprising the first donor III-N layer bonded onto the target wafer, wherein a thickness of the top surface layer is equal to or lower than 200 nm;
epitaxially growing an epitaxial III-N semiconductor layer stack on top of the top surface layer, wherein the epitaxial III-N semiconductor layer stack comprises:
a first active III-N layer;
a second active III-N layer on top of the first active III-N layer;
with a two-dimensional Electron gas between the first active III-N layer and the second active III-N layer;
forming a gate contact contacting the second active III-N layer in a gate region; and
forming a substrate galvanic contact contacting the target substrate.

2. The method of claim 1, wherein the providing the target wafer further comprises forming a target dielectric layer on top of the target substrate, wherein a thickness of the target dielectric layer is equal to or lower than 50 nm.

3. The method of claim 2, wherein the forming the donor film further comprises forming a donor dielectric layer on top of the first donor III-N layer, wherein a thickness of the donor dielectric layer is equal to or lower than 10 nm.

4. The method of claim 3, wherein bonding the donor film to the target wafer corresponds to bonding the donor dielectric layer to the target dielectric layer, thereby forming a dielectric layer stack comprising the target dielectric layer and the donor dielectric layer.

5. The method of claim 3, wherein forming the donor film further comprises providing a second donor III-N epitaxial layer between the first donor III-N layer and the donor dielectric layer; and wherein a thickness of the second donor III-N epitaxial layer is equal to or lower than 10 nm.

6. The method according to claim 5, wherein the providing the second donor III-N epitaxial layer corresponds to forming, between the first donor III-N layer and the donor dielectric layer, a second donor III-N epitaxial layer epitaxially grown as a N-polar layer.

7. The method of claim 1, wherein forming the donor film comprises epitaxially growing the first donor III-N layer, and wherein epitaxially growing the first donor III-N layer corresponds to epitaxially growing a first section and a second section of the first donor III-N layer and epitaxially growing a third donor III-N epitaxial layer between the first section and the second section of the first donor III-N layer; and wherein the donor wafer and the target wafer are separated by splitting the first section of the first donor III-N layer.

8. The method of claim 7, wherein the third donor III-N epitaxial layer comprises Aluminum Nitride.

9. The method of claim 1, wherein forming the donor film comprises epitaxially growing the first donor III-N layer, and wherein epitaxially growing the first donor III-N layer corresponds to epitaxially growing the first donor III-N layer as a N-polar layer.

10. The method of claim 1, further comprising:
providing a temporary donor wafer comprising a temporary sacrificial substrate and a temporary first donor III-N layer;
bonding the temporary first donor III-N layer to the sacrificial substrate; and
separating the temporary donor wafer and the donor wafer by splitting the temporary first donor III-N layer, or separating the temporary donor wafer and the donor wafer at the interface between the temporary first donor III-N layer and the temporary sacrificial substrate, thereby forming on the donor wafer the first donor III-N layer at least partially comprising the temporary first donor III-N layer bonded onto the donor wafer.

11. The method of claim 10, wherein providing a temporary donor wafer corresponds to:
providing the temporary sacrificial substrate; and
epitaxially growing the temporary first donor III-N layer on top of the temporary sacrificial substrate;
or wherein providing a temporary donor wafer corresponds to growing the temporary first donor III-N layer as a Ga-polar bulk III-N layer and bonding the temporary first donor III-N layer to the sacrificial substrate corresponds to tiling the sacrificial substrate with one or more temporary donor wafers by bonding the temporary first donor III-N layers of the temporary donor wafers to the sacrificial substrate.

12. The method of claim 1, further comprising:
forming a source contact contacting the second active III-N layer in a source region; and
forming a drain contact contacting the second active III-N layer in a drain region.

13. The method of claim 12, further comprising:
etching the epitaxial III-N semiconductor layer stack away in one or more regions;
in the one or more regions, forming one or more recesses extending through the top surface layer until at least partially into the target substrate, wherein the one or more recesses are not positioned between the gate region and the source region or between the gate region and the drain region, thereby defining one or more electrical isolation regions;
providing a dielectric layer in one or more of the recesses; and
forming a contact in the one or more electrical isolation regions on top of the dielectric layer, thereby forming one or more electrical isolations.

14. A high electron mobility transistor (HEMT), comprising:
a target substrate;
a top surface layer on top of the target substrate, wherein a thickness of the top surface layer is less than 200 nm;
an epitaxial III-N semiconductor layer stack on top of the top surface layer, wherein the epitaxial III-N semiconductor layer stack comprises:
a first active III-N layer;
a second active III-N layer on top of the first active III-N layer;
with a two-dimensional Electron gas between the first active III-N layer and the second active III-N layer;
a gate contact contacting the second active III-N layer in a gate region; and
a substrate galvanic contact contacting the target substrate.

15. The HEMT of claim 14, wherein the HEMT further comprises between the target substrate and the top surface layer at least two dielectric layers, wherein a thickness of the at least two dielectric layers is equal to or lower than 60 nm.

16. The method of claim 1, wherein the forming the donor film further comprises forming a donor dielectric layer on top of the first donor III-N layer, wherein a thickness of the donor dielectric layer is equal to or lower than 10 nm.

17. The method of claim 2, wherein bonding the donor film to the target wafer corresponds to bonding the donor dielectric layer to the target dielectric layer, thereby forming a dielectric layer stack comprising the target dielectric layer and the donor dielectric layer.

18. The method of claim 4, wherein forming the donor film further comprises providing a second donor III-N epitaxial layer between the first donor III-N layer and the donor dielectric layer; and wherein a thickness of the second donor III-N epitaxial layer is equal to or lower than 10 nm.
